(19) United States
(12) Patent Application Publication
(10) Pub. No.: US 2003/0183926 A1
(43) Pub. Date: Oct. 2, 2003

(54) Semiconductor device and semiconductor packaging device

(75) Inventors: Tadayuki Shimizu, Tokyo (JP); Masaki Tsukude, Tokyo (JP); Takafumi Takatsuka, Tokyo (JP); Hirotoshi Sato, Tokyo (JP)

Correspondence Address: MCDERMOTT, WILL & EMERY, 600 13th Street, N.W., WASHINGTON, DC, 20005-3096, US

(73) Assignee: Mitsubishi Denki Kabushiki Kaisha

(21) Appl. No.: 10/252,679

(22) Filed: Sep. 24, 2002

(30) Foreign Application Priority Data
Mar. 28, 2002 (JP) P2002-91513

(51) Int. Cl. H01L 23/34

(52) U.S. Cl. 257/723

(57) ABSTRACT

A plurality of semiconductor chips are mounted in the same package, and a power supply is shared by the output circuits of the chips. In this case, even though the internal circuit power supplies of the chips are turned off, since an output circuit is in an ON state, a through current may flow from another chip. Therefore, a circuit for setting transistors constituting the output circuits of the chips in high-impedance states when the power supplies for the internal circuits of the respective semiconductor chips are turned off is added.

### BACKGROUND OF THE INVENTION

1. Field of the Invention

The present invention relates to a device in which a plurality of semiconductor chips are mounted in the same package and, more particularly, to a semiconductor integrated circuit in which a through current is prevented from being flowed in output circuits of chips when a power supply is turned off.

2. Description of the Background Art

In a device having an internal power supply and an output power supply, when chips are not used, both the internal power supply and the output power supply are turned off, and only one of the power supplies is not turned off. However, as shown in FIG. 1, in a device in which a plurality of (two in FIG. 1) semiconductor chips A and B are mounted in the same package, and the chips have independent internal power supplies VDD1 and VDD2, respectively. When an output power supply VDDQ1 is shared by both the chips, even though the internal power supply of an unnecessary one of the chips is turned off, the output power supply VDDQ1 is kept ON because the output power supply is shared by both the chips.

In this case, since a power is continuously applied to the output circuit, an output current of another chip set in an ON state flows in the output circuit as a through current to cause an erroneous operation.

The present invention is made to solve the above-mentioned problems, and it is an object of the present invention to prevent through current from flowing in output circuit for chips when a power supply is turned off.

### SUMMARY OF THE INVENTION

A semiconductor device is constituted by an internal circuit to which a power is supplied by a first power supply and an output circuit to which a power is supplied by a second power supply. According to the present invention, in order to solve the above problems, the semiconductor device includes means for turning off an output transistor in the output circuit when a power is supplied to the output circuit by the second power supply while the power supply by the first power supply is stopped.

In order to turn off an output transistor, when the output transistor is a p-type MOS transistor, the means supplies a potential equal to that of the second power supply to the gate electrode of the transistor. On the other hand, when the output transistor is an n-type MOS transistor, a ground potential is supplied to the gate electrode of the transistor.

When two semiconductor devices described above (a first semiconductor device and a second semiconductor device) are mounted,

a first power of the first semiconductor device is supplied from a first external power supply,

a first power of the second semiconductor device is supplied from a second external power supply, and

second powers of the first and second semiconductor devices are supplied from a third external power supply.

When the first and second semiconductor devices are mounted in the same package, pins of a package for supplying powers from a second power to the first and second semiconductor devices can be shared by the first and second semiconductor devices.

### BRIEF DESCRIPTION OF THE DRAWINGS

FIG. 1 is a diagram showing a configuration in a package of a semiconductor integrated circuit.

FIG. 2 is a diagram showing the appearance of a package of the semiconductor integrated circuit according to the first embodiment of the present invention.

FIG. 3 is a diagram showing a configuration in a package of a semiconductor integrated circuit shown in FIG. 2.

FIG. 4 is a diagram showing the appearance of a package of the semiconductor integrated circuit according to the second embodiment of the present invention.

FIG. 5 is a diagram showing the configuration in the package of the semiconductor integrated circuit shown in FIG. 4.

### DETAILED DESCRIPTION OF PREFERRED EMBODIMENTS

First Embodiment

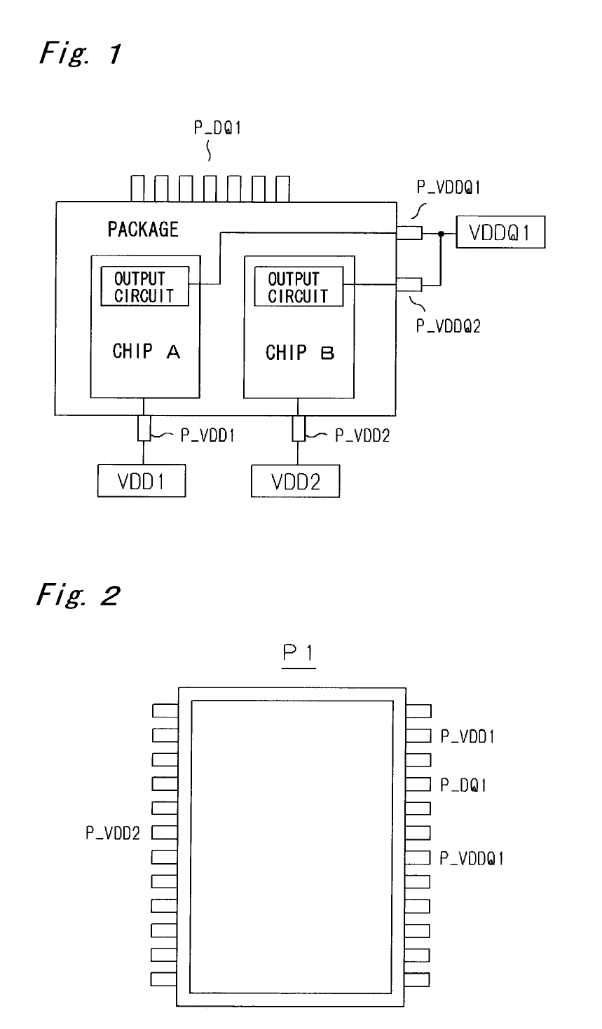

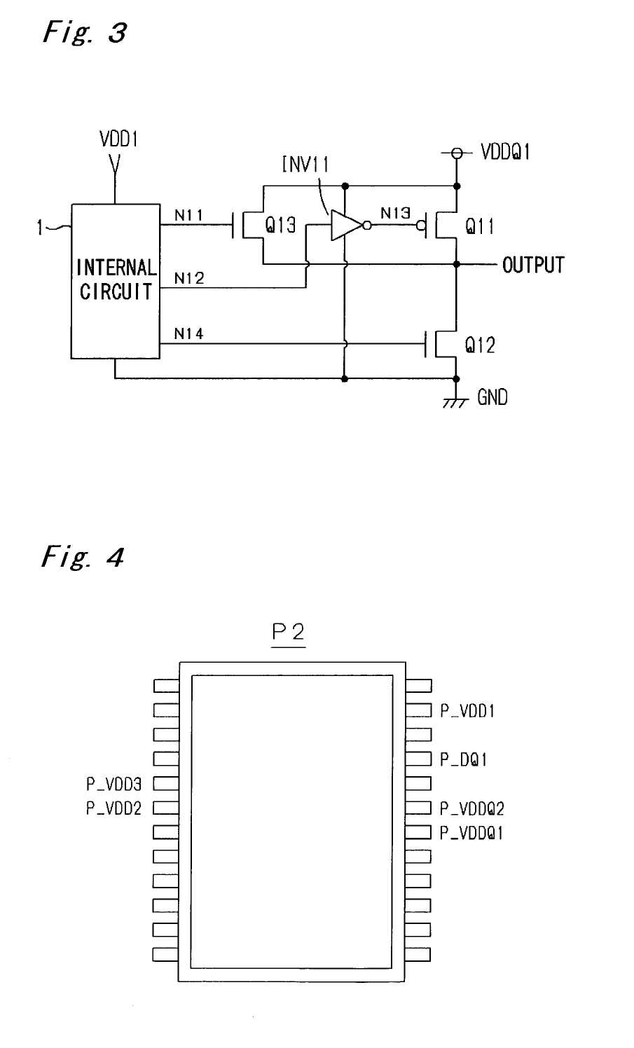

FIG. 2 shows the appearance of a package P1 to which the present invention is applied. Two semiconductor chips A and B are mounted inside the package P1. The internal configuration is the same as that in FIG. 1. FIG. 3 shows the circuit configuration of the chip A. An inverter INV11 or the like serving as a logic device is added to the circuit configuration. The chip B has the same circuit configuration as that of the chip A.

For example, the chip A is a flash memory, and the chip B is a pseudo SRAM (having a DRAM configuration which can be used as an SRAM to perform refreshing inside the configuration). In order to reduce a current consumption, an unnecessary chip is often turned off.

This package P1 comprises a pin P_VDD1 to be connected to an internal power supply VDD1 of the chip A, a pin P_VDD2 to be connected to an internal power supply VDD2 of the semiconductor chip B, a shared pin P_VDDQ1 to be connected to an output (input/output) power supply VDDQ1 shared by both the chips A and B, and a data input/output pin P_DQ1 shared by both the chips A and B.

The output circuits of the chips A and B has dedicated power supply pins (pins P_VDDQ1 and P_VDDQ2 as shown in FIG. 1), and both the pins may be connected to each other outside the package. Data input/output pins are arranged for chips, respectively. In addition, the data input/output pin may be a dedicated data output pin.

In the circuit configuration shown in FIG. 3, a power is supplied to an internal circuit 1 by the internal power supply VDD1. Powers are supplied to transistors Q11, Q12, and Q13 and the inverter INV11 which constitute the output circuit by the output power supply VDDQ1. A power is supplied to the output circuit of the chip B also by the output power supply VDDQ1.

The operation of the output circuit section will be described below. In order to pause the chip A, when only the internal power supply VDD1 for the chip A is turned off, charges pass through the nodes of the internal circuit 1 of the chip A a predetermined time after, and all the nodes are set at GND potentials. Nodes N11, N12, and N14 shown in figure are set at GND potentials, and the transistor Q12 is turned off. Since a power is supplied to the inverter INV11, a potential “H” (i.e., a potential equal to that of the power supply VDDQ1) is output from the inverter INV11. Since the potential “H” is supplied to the gate of the transistor Q11, the transistor Q11 is turned off.

When the transistor Q11 is an n-type channel, a potential “L” (i.e., GND potential) is output from the inverter INV11 in the power OFF state of the internal circuit 1.

More exactly, when the transistor Q11 is a p-type channel, a potential (output power supply voltage-gate potential of the transistor) of the transistor Q11 is set to be the threshold value of the transistor Q11 or more. When the transistor Q11 is an n-type channel, the gate potential of the transistor Q11 is set to be the threshold value of the transistor Q11 or less.

In this manner, when the internal power supply VDD1 of the internal circuit 1 is turned off, both the transistors Q11 and Q12 of the output section are turned off to set a high-impedance state. For this reason, even though the output power supply VDDQ1 is in an ON state, a current flowing in the output section of the other chip B does not flow in the output section of the chip A as a through current.

As a matter of course, in an OFF state of the power supply VDD1, the potential of the node N11 is the threshold value of the transistor Q13 or less, the potential of the node N14 is the threshold value of the transistor Q12 or less, and the potential of the node N13 is the threshold value of the transistor Q11 or more. In this case, the transistors Q11, Q12, and Q13 can be turned off.

Second Embodiment.

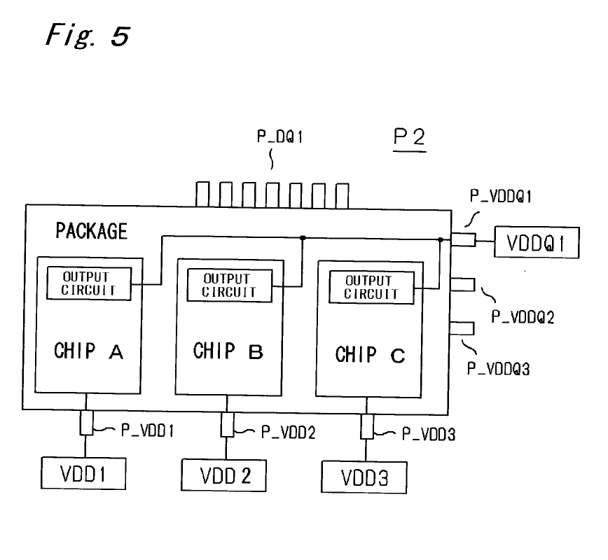

The appearance of a package P2 in which three chips A, B, and C are mounted is shown in FIG. 4. The internal structure of the package P2 is shown in FIG. 5. Reference symbols P_VDD1, P_VDD2, and P_VDD3 denote pins for internal power supplies for the chips A, B, and C. Reference symbol PVDDQ1 is a pin for an out put power supply of, e.g., the chip A, and reference symbol PVDDQ2 denotes a pin for an output power supply shared by, e.g., the chips B and C. One output power supply may be shared by the output circuits of the three chips A, B, and C.

Even though three or more chips are mounted in the package as described above, the transistor of the output section of the chip in which the power supply of the internal circuit is turned off can be turned off. For this reason, a through current does not flow in the output section.

In a conventional art, power supply pins for output circuits are extracted for the chips from a package, respectively. For this reason, the output circuit of the chips can be independently turned off. In this manner, the problem of the through current in the output circuits can be solved. However, respective power supply pins are required for the output circuits of the chips. When the output circuits of the present invention are used, even though a power supply pin is shared by the output circuits of the plurality of chips, no problem of a through current in the output circuits is generated. Therefore, the number of pins can be reduced.

According to an aspect of the present invention, a semiconductor device comprises: an internal circuit to which a first power is supplied; and an output circuit to which a second power different from the first power is supplied, which includes an output transistor for outputting data to the outside depending on an output signal from the internal circuit, and which turns off the output transistor when the supply of the first power is stopped and the second power is supplied. For this reason, when the supply of the first power is stopped, and when the second power is supplied, a through current can be prevented from flowing in the output transistor.

According to another aspect of the present invention, when a transistor constituting the output transistor is a p-type MOS transistor, the output circuit gives a potential equal to that of the second power to a gate electrode of the p-type MOS transistor, and, when the transistor constituting the output transistor is an n-type transistor, the output circuit gives a ground potential to a gate electrode of the n-type MOS transistor. With this configuration, the output transistor can be stably turned off, and a through current can be canceled.

According to still another aspect of the present invention, first and second semiconductor devices each including an internal circuit to which a first power is supplied and an output circuit to which a second power different from the first power is supplied, which includes an output transistor for outputting data to the outside depending on an output signal from the internal circuit, and which turns off the output transistor when the supply of the first power is stopped and when the second power is supplied are mounted in the semiconductor packaging device,

a first power of the first semiconductor device is supplied from a first external power supply,

a first power of the second semiconductor device is supplied from a second external power supply, and

second powers of the first and second semiconductor devices are supplied from a third external power supply. For this reason, the supply of the first power of the first or second semiconductor device is stopped, a through current does not flow in the output transistor.

According to still another aspect of the present invention, first and second semiconductor devices are mounted in the same package, and a pin of a package for supplying a second power to the first and second semiconductor devices is shared by the first and second semiconductor devices. Even though the pin is shared as described above, a through current does not flow in an output transistor.

What is claimed is:

1. A semiconductor device comprising:
an internal circuit to which a first power is supplied; and
an output circuit to which a second power different from said first power is supplied, which includes an output transistor for outputting data to the outside depending on an output signal from said internal circuit, and which turns off said output transistor when the supply of said first power is stopped and the second power is supplied.

2. A semiconductor device according to claim 1, wherein, when a transistor constituting the output transistor is a p-type MOS transistor, the output circuit gives a potential equal to the second power to a gate electrode of the p-type MOS transistor, and, when the transistor constituting the output transistor is an n-type transistor, the output circuit gives a ground potential to a gate electrode of the n-type MOS transistor.

3. A semiconductor packaging device, wherein first and second semiconductor devices each including an internal circuit to which a first power is supplied and an output circuit to which a second power different from said first power is supplied, which includes an output transistor for outputting data to the outside depending on an output signal from said internal circuit, and which turns off said output transistor when the supply of said first power is stopped and when the second power is supplied are mounted in the semiconductor packaging device,
a first power of said first semiconductor device is supplied from a first external power supply,
a first power of said second semiconductor device is supplied from a second external power supply, and
second powers of the first and second semiconductor devices are supplied from a third external power supply.

4. A semiconductor packaging device according to claim 3, wherein
the first and second semiconductor devices are mounted in the same package, and
a pin of a package for supplying a second power to said first and second semiconductor devices is shared by the first and second semiconductor devices.
